(19) United States
(12) Patent Application Publication
(10) Pub. No.: US 2007/0211776 A1
(43) Pub. Date: Sep. 13, 2007

(54) SEMICONDUCTOR LASER HAVING IMPROVED FACETS OF THE RESONATOR

(75) Inventors: Yasuaki Yoshida, Tokyo (JP); Yasuyuki Nakagawa, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 11/680,674

(22) Filed: Mar. 1, 2007

(30) Foreign Application Priority Data
Mar. 13, 2006 (JP) 2006-067307
Mar. 31, 2006 (JP) 2006-097786

(51) Int. Cl. H01S 5/00

(52) U.S. Cl. 372/49.01

(57) ABSTRACT

In a semiconductor laser having a first facet (front facet) through which laser light is emitted and a second facet (rear facet), and a first coating film composed of a single-layer dielectric film on the first facet. The oscillating wavelength of the laser light is λ and the refractive index of the dielectric film is n. The thickness of the dielectric film is within a range between 5% and 50% of λ/4n.

### BACKGROUND OF THE INVENTION

1. Field of the Invention

The present invention relates to a semiconductor laser used in an optical disk system or optical communications, and more specifically, the present invention is preferably applied to a blue semiconductor laser using a nitride semiconductor.

2. Background Art

A semiconductor laser is widely used in an optical disk system or optical communications. The semiconductor laser is equipped with a resonator for generating laser beams. An end portion thereof is provided with a front facet for emerging laser beams, and the other end portion is provided with a rear facet. Each of the front and rear facets is coated with an insulating film known as a coating film for reducing the operating current of the semiconductor laser, preventing return light, and raising outputs.

In Japanese Patent No. 3080312, or in Japanese Unexamined Patent Publication No. 2002-100830, 2003-101126, 2004-296903, a semiconductor laser with high output is disclosed. The laser has a coating film of a low reflectivity formed on the front facet side, and a coating film of a high reflectivity formed on the rear facet side. The reflectivity of the coating film in the rear facet side is normally 60% or more, preferably 80% or more. The lower reflectivity of the front facet is not necessarily better, but the reflectivity is selected depending on the properties required to the semiconductor laser. For example, in a semiconductor laser for exciting a fiber amplifier used together with fiber grating, the reflectivity is about 0.01 to 3%, in a normal high-output semiconductor laser, it is about 3 to 7%, and when countermeasure against return light is required, a reflectivity of about 7 to 10% is selected.

In recent years, along with the shortened oscillation wavelength of laser beams, the laser beams have been easily absorbed in a coating film. The coating film functions also as a film for protecting an facet, known as a passivation film. Consequently, when the oscillation wavelength of laser beams is shortened, conventionally used materials and forming conditions of the coating film have caused a problem that crystals in the vicinity of facets are easily deteriorated.

### SUMMARY OF THE INVENTION

The present invention has been developed to solve the above-described problems, and therefore it is an object of the present invention to provide a long-life semiconductor laser wherein the effect of light absorption by a coating film formed on the facet of a resonator is suppressed.

The above object is achieved by a semiconductor laser that includes a resonator disposed along the traveling direction of laser beams, a first facet formed in one end portion of the resonator, from which the laser beams emit, a second facet formed in the other end portion of the resonator, and a first coating film consisting of a single layer dielectric film is formed on at least one of the first facet and the second facet, and when the oscillating wavelength of the laser beams is denoted by λ and the refractive index of the dielectric film is denoted by n, the thickness of the dielectric film is within a range between 5% and 50% of λ/4n.

According to the present invention, the effect of light absorption by a coating film formed on the facet of a resonator can be minimized, and a long-life semiconductor laser can be obtained.

Other features and advantages of the invention will be apparent from the following description taken in connection with the accompanying drawings.

### BRIEF DESCRIPTION OF DRAWINGS

FIG. 1 shows a perspective view of a semiconductor laser; and

FIG. 2 shows the rates of defects of the semiconductor lasers.

### DETAILED DESCRIPTION OF THE PREFERRED EMBODIMENTS

Embodiments of the present invention will be described below referring to the drawings. In the drawings, the same or equivalent parts will be denoted by the same reference numerals, and the description thereof will be simplified or omitted.

### First Embodiment

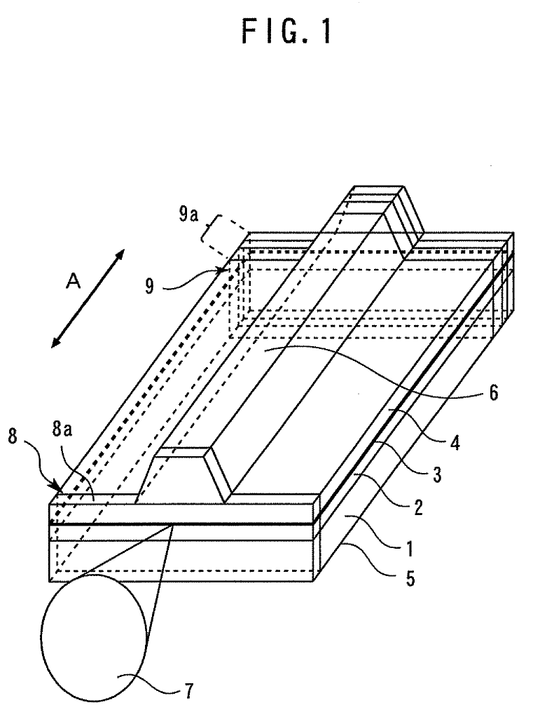

FIG. 1 shows a perspective view of a semiconductor laser according to a first embodiment of the present invention. This semiconductor laser is a gallium nitride semiconductor laser that generates blue laser beams, and is formed using a GaN substrate 1. On the GaN substrate 1 are laminated an n-type clad layer 2, an active layer 3, and a p-type clad layer 4. A ridge-shaped positive electrode 6 is formed thereon. The back face of the GaN substrate 1 is equipped with a negative electrode 5. A resonator is composed of the substrate, the clad layer, the active layer, and the electrodes along A direction, that is the traveling direction of the laser beams. An end portion of the resonator is provided with a first facet (front facet) 8 from which laser beams emit, and the other end portion is provided with a second facet (rear facet) 9.

The first facet 8 is provided with a first coating film 8a, and the second facet 9 is provided with a second coating film 9a having a higher reflectivity than that of the first coating film 8a. By thus making the reflectivity of the coating film on the second facet 9 side higher than the reflectivity of the coating film on the first facet 8 sides the loss of laser beams from the second facet 9 side is suppressed, and a high-output semiconductor laser can be obtained. As the second coating film 9a, for example, a multilayer film formed by laminating an SiO₂ film and a Ta₂O₅ film is used. Since this film has a reflectivity of as high as about 90%, the loss of laser beams from the second facet 9 side can be effectively suppressed. Thereby, a high beam output of 50 mW or more can be obtained from the first facet 8 side.

When the above-described semiconductor laser is operated, a forward voltage is applied from the positive electrode 6 to the negative electrode 5. Then, holes are injected from the p-type clad layer 4 into the active layer 3, and electrons are injected from the n-type clad layer 2 into the active layer 3. These holes are combined with electrons to generate laser beams 7 from the active layer 3, The laser beams 7 travel in the active layer 3 along A direction, and are emitted from the first facet 8 side.

As the first coating film 8a, a single-layer dielectric film, such as an aluminum oxide (Al₂O₃) film can be used. This dielectric film is formed, for example, by a sputtering method using electron cyclotron resonance (hereafter referred to as “ECR”). In a conventional art, when the reflectivity of the first facet 8 was made 10% or less, the thickness of the above-described dielectric film was a value of λ/4n (λ: oscillating wavelength of laser beams, n: refractive index of the dielectric film) to which a correction value to adjust the refractive index was added, or an integral multiple (twice or more) of λ/4n to which the above-described correction value was added. While in the first embodiment, the thickness of the above-described dielectric film is within a range between 5% and 50%, preferably a range between 5% and 20% of λ/4n. For example, when an Al₂O₃ film is used as the above-described dielectric film, since the oscillating wavelength λ of blue laser beams is 400 nm and the refractive index n of the Al₂O₃ film is 1.7, the thickness of the above-described coating film 8a is within a range between 2.9 nm and 29.4 nm (a range between 5% and 50% of λ/4n), preferably within a range between 2.9 nm and 11.8 nm (a range between 5% and 20% of λ/4n). Here, the thickness of the above-described aluminum oxide (Al₂O₃) film is about 5 nm.

As the above-described dielectric film, other than aluminum oxide (Al₂O₃) described above, a single-layer film composed of one selected from a group consisting of aluminum nitride (AlN), amorphous silicon, titanium oxide (TiO₂), niobium oxide (Nb₂O₅), zirconium oxide (ZrO₂), tantalum oxide (Ta₂O₅), silicon oxide (SiO₂), hafnium oxide (HfO₂) can also be used. Using any of the above-described films, the thickness is made to be within a range between 5% and 50%, preferably between 5% and 20% of λ/4n. For example, when tantalum oxide (Ta₂O₁ reflectivity=2.3) is used, the value of λ/4n becomes about 43 nm; therefore, the thickness of the first coating film 8a is made to be within a range between 2.2 nm and 21.7 nm (a range between 5% and 50% of λ/4n), preferably a range between 2.2 nm and 8.7 nm (a range between 5% and 20% of λ/4n). Here, the thickness of the above-described tantalum oxide (Ta₂O₅) film is made to be about 4 nm.

Next, the reason why the thickness of the dielectric film is made to be 50% or less of λ/4n will be described. In a conventional art, as described above, the thickness of the first coating film 8a was made to be a value close to λ/4n, or a value close to an integral multiple (twice or more) of λ/4n. Here, if the oscillating wavelength of laser beams is shortened as in a blue laser, the attenuation coefficient κ (imaginary part K in complex refractive index n=n₀−κ), which is a property value of the coating film elevates, Therefore, the absorption coefficient α obtained by multiplying the attenuation coefficient K by 4n/λ (λ: oscillating wavelength of laser beams) elevates when the oscillating wavelength of laser beams is shortened. Furthermore, the intensity of light traveling in the Z-direction in the film is reduced in proportion to EXP (−αZ). In other words, when the oscillating wavelength of laser beams is shortened, the laser beams are easily absorbed upon passing through the coating film, and the intensity thereof is reduced.

Here, the absorption edge (light having a wavelength shorter than this value is absorbed) of titanium oxide (TiO₂) and tantalum oxide (Ta₂O₅) of the above-described dielectric films is around 350 nm. The absorption edge of other films, specifically aluminum oxide (Al₂O₃), aluminum nitride (AlN) amorphous silicon, niobium oxide (Nb₂O₅), zirconium oxide (ZrO₂), silicon oxide (SiO₂), and hafnium oxide (HfO₂) is around 200 nm.

When a film having an absorption edge of around 200 nm is used as a coating film, and the film is ideally formed, since the absorption edge is sufficiently shorter than the oscillating wavelength of blue laser beams (400 nm), the laser beams are little absorbed. Whereas, when a film having an absorption edge of around 350 nm is used as a coating film, the absorption edge is an indispensable value compared with the above-described oscillation wavelength. Therefore, even if the coating film is ideally formed, the absorption of laser beams cannot be ignored to the oscillating wavelength of blue laser beams (400 nm). For the oscillating wavelength band of red laser beams (up to 680 nm), the absorption is a fraction of it.

The attenuation coefficient may become indispensable due to a film forming method or the like regardless of the absorption edge value of the coating film. The thin film formed as the coating film is preferably formed to be single-crystalline or amorphous. However, a columnar structure may be formed by the effect of the film forming method or the substrate when the film is formed. If such a structure is formed, moisture is adsorbed in the film when the coating film is exposed to the atmosphere in subsequent steps. Particularly when the coating film is formed by vapor deposition, moisture is easily taken in the film. Also when the coating film is formed by sputtering, the sputtering gas such as argon may be taken in the film. As a result, with the shortening of oscillating wavelength of laser beams, the attenuation coefficient of the coating film may exceed the original property value.

If the attenuation coefficient thus exceeds the original property value, particularly in a blue laser (oscillating wavelength: 400 nm), the absorption of laser beams occurs easily in the first coating film 8a compared with a red laser (oscillating wavelength: 680 nm) or a laser having a oscillating wavelength of 780 nm. Therefore, particularly in a blue laser, crystals in the vicinity of the facets become easily deteriorated by the heat generation of the coating film.

In the first embodiment, the thickness of the above-described dielectric film is 50% or less of λ/4n. As described above, since the intensity of light is expressed by EXP (−αZ), when the thickness of the dielectric film is λ/4n, the intensity of light having passed through the dielectric film becomes EXP (−κ·λ/n); and when the thickness of the dielectric film is 50% of λ/4n, the intensity of light having passed through the dielectric film becomes EXP (−κ/2·λ/n). Therefore, if the thickness of the dielectric film is 50% of λ/4n, the effect of light absorption is the same as when the thickness of the dielectric film is λ/4n even if the attenuation coefficient κ is twice that in the conventional art. Further preferably, the thickness of the above-described dielectric film is 20% or less of λ/4n. In this case, even if the attenuation coefficient of the coating film is 5 times or more of the original property value, the effect can be suppressed to equal to or smaller than in the conventional art. Thereby, the reliability of the device can be improved, and a long-life semiconductor laser can be obtained. Although the effect of light absorption has been described above, for the effect of mechanical stress when the dielectric film has a polycrystalline or columnar structure, the equivalent effect can be obtained by reducing the thickness of the dielectric film.

Next, the reason why the thickness of the above-described dielectric film is made to be 5% or more of λ/4n will be described. In a particularly high-output semiconductor laser, if the thickness of the above-described dielectric film is less than 5% of λ/4n, impurities such as carbon adhere on the facets of the resonator due to a photochemical action to easily deteriorate the device. If the facets are made to be uncoated (no coating film is provided), impurities adhere on the facets to raise the interface state of crystals. In this case, the vicinities of the facets generate heat due to nonradiative recombination, and the band gap energy of the active layer is reduced. Then, deterioration due to catastrophic optical damage (hereafter abbreviated as “COD”) occurs easily.

While in the first embodiment, the thickness of the dielectric film is made to be not less than 5% of λ/4n. Thereby, the deterioration of the device due to COD can be suppressed. Therefore, the deterioration of the device is prevented, and a long-life semiconductor laser can be obtained.

However, if the thickness of the first coating film 8a is made to be not more than 50% of λ/4n (λ: oscillating wavelength of laser beams, n: reflectivity of the dielectric film), the reflectivity of the first facet becomes a value around 18% as in the uncoated case. Therefore, when compared with the case wherein a low-reflectivity coating film of a reflectivity of about 6% is formed on the first facet, the reflectivity of the facet becomes higher. Then, a problem that the slope efficiency (ΔP/ΔI, where ΔI is an increment of current injected in the laser, and ΔP is an increment of optical output of laser beams) is lowered with the rise in the reflectivity arises.

Here, when the facets of the resonator is made uncoated, there is the following relationship between the reflectivity R₀ of the facets and the refractive index n₀ of the semiconductor:

Rₒ={(n₀−1)²/(n₀+1)²}×100(%) (Equation 1)

A laser having an oscillating wavelength of 780 nm or a red laser is formed of a GaAs material. Therefore, the refractive index of the facets n₀ is 3.6. At this time, from Equation 1, the reflectivity R₀ of the facets is about 32%. Whereas, the refractive index of the facets of a GaN laser is 2.5, and from Equation 1, the reflectivity R₀ of the facets is about 18%. Specifically, in the GaN semiconductor laser, the rise in the reflectivity when the thickness of the coating film on the facets is made to be λ/4n to uncoated can be minimized compared with the case wherein the thickness of the coating film on the facets is made to be λ/4n to uncoated in a laser having an oscillating wavelength of 780 nm or a red laser.

Similarly, when the coating film of the facets in a GaN semiconductor laser is thinned from λ/4n (λ: oscillating wavelength of laser beams, n: reflectivity of the dielectric film) to not more that 50% thereof, the rise in the reflectivity can be minimized compared with the case wherein the same film thinning is performed in a laser having an oscillating wavelength of 780 nm or a red laser.

Consequently, when the above-described film thinning is performed in a GaN semiconductor laser, since the reflectivity of the facets rises, the slope efficiency is reduced; however, the reduction becomes smaller than the case when the same film thinning is performed in a laser having an oscillating wavelength of 780 nm or a red laser. When the reflectivity of the facets rises, the threshold current to generate laser beams lowers. Therefore, even if the reflectivity rises a little, the operation current in the rated output can be designed in the same way as in the case wherein the reflectivity does not rise. Thereby, there in no need to elevate the driving current in operation. Therefore, the lowering of reliability of the coating film can be suppressed.

Next, the reliability of a semiconductor laser according to the first embodiment will be described. The reliability tests of the first coating film shown in FIG. 1 were carried out on the case when the formed film had a thickness of the present invention and the case when the formed film had a thickness of a conventional art. Both the coating films of the present invention and the conventional art were Al₂O₃ films formed by ECR sputtering. The film thickness of the present invention was about 5 nm (about 8.5% of λ/4n), and the film thickness of the conventional art was about 118 nm (twice of λ/4n). The reflectivities of the coating films of the present invention and the conventional art were 18.1% and 18.4%, respectively. Five samples were prepared for each of the present invention and the conventional art. A pulse of 120 mW output was applied at 75° C. to these samples, and the occurrence of defects after 300 hours was checked. As a result, no defects occurred in the samples of the present invention (0 defects in 5 samples), and defects occurred in all the samples of the conventional art (5 defects in 5 samples). From these results, it was found that the reliability of a semiconductor laser was significantly improved, and the life was elongated by the present invention.

According to the first invention, as described above, the effect of the light absorption of the coating film formed on the facets of the resonator can be minimized, and a long-life semiconductor laser can be obtained.

### Second Embodiment

A semiconductor laser according to the second embodiment will be described. Here, the description will be focused around difference from the first embodiment. In the second embodiment, a tantalum oxide (Ta₂O₅) film is formed as a first coating film 8a using a vapor deposition method, and the reliability of the semiconductor laser when the film thickness was made to be within a range between 12% and 200% of λ/4n (λ: oscillating wavelength of laser beams, n: reflectivity of the dielectric film) is checked. Specifically, the reliability of the semiconductor laser was evaluated when the thickness of the first coating film 8a includes the range larger than 50% of λ/4n.

Semiconductor lasers wherein the thickness of the first coating film 8a is made to be about 5 nm (about 12% of λ/4n), about 10 nm (about 23% of λ/4n), about 25 nm (about 58% of λ/4n, slightly thicker than the first embodiment), about 43.5 nm (about 100% of λ/4n, film thickness of a conventional art film), and about 87 nm (about 200% of λ/4n) were called Specifications A, B, C, D, and E. Five samples of each specification, a total of 25 samples were prepared.

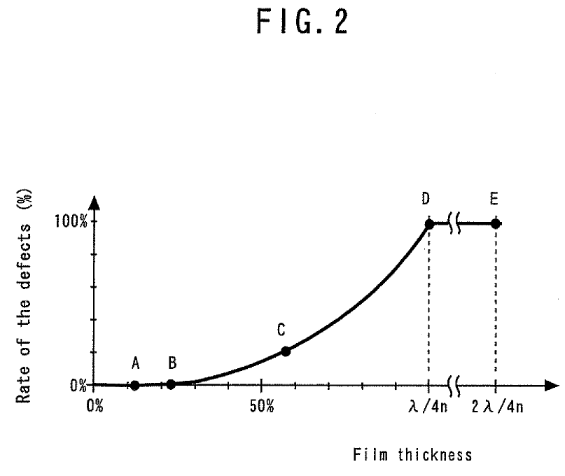

A pulse of 120 mW output was applied at 75° C. to these samples, and the occurrence of defects after 100 hours was checked. As a result, the numbers of defects that occurred in Specifications A, B, C, D, and E were 0, 0, 1, 5, and 5, respectively. Specifically, as FIG. 2 shows, the rates of defects that occurred in Specifications A, B, C, D, and E were 0%, 0%, 20%, 100%, and 100%, respectively.

From FIG. 2, it is known that the reliability of a semiconductor laser is lowered when the thickness of the first coating film 8a is larger than 50% of λ/4n. Therefore, from the results of the first and second embodiments, the reliability of a semiconductor laser can be significantly improved, and the life thereof can be elongated by making the thickness of the first coating film 8a within a range between 5% and 50% of λ/4n.

### Third Embodiment

A semiconductor laser according to the third embodiment will be described. Here, the description will be focused around difference from the first embodiment. In the first embodiment, an example wherein a dielectric film is formed as the coating film of the first facet by ECR sputtering was shown. In the third embodiment, the dielectric film is formed using a vapor deposition method, a sputtering method other than ECR, or a chemical vapor deposition (hereafter abbreviated as “CVD”) method. As in the first embodiment, the film thickness is made within a range between 5% and 50%, preferably 5% and 20% of λ/4n (λ: oscillating wavelength of laser beams, n: reflectivity of the dielectric film). Thereby, the effect as in the first embodiment can be obtained. Other configuration is same as in the first embodiment.

By forming the dielectric film using any of a vapor deposition method, a sputtering method, and a chemical vapor deposition method, the quantities of oxygen and nitrogen can be adjusted when the dielectric film is formed, and the relative proportions of the metal and oxygen, or metal and nitrogen contained in the dielectric film can be changed (excluding the cases wherein the dielectric film is amorphous silicon). Thereby, in addition to the effect obtained in the first and second embodiments, the reflectivity and absorption coefficient of the coating film can be adjusted.

### Fourth Embodiment

A semiconductor laser according to the fourth embodiment will be described. Here, the description will be focused around difference from the first to third embodiments. With rise in the output of a semiconductor laser, reliability is lowered when the coating films themselves on the first and second facets shown in FIG. 1 deteriorate. In the fourth embodiment, a structure wherein the resistance of the coating film itself to laser beams is improved to suppress the lowering of the reliability will be described.

One of the indices for laser-beam resistance is energy required for isolating a molecule composed of 2 or more atoms into atomic units. In the fourth embodiment, this index was used and a film having a high energy among the dielectric films shown in the first to third embodiments was used as the coating film. Thereby, the resistance to laser beams can be intensified, and reliability can be improved.

In the first embodiment, aluminum oxide (Al₂O₃), aluminum nitride (AlN), amorphous silicon, titanium oxide (TiO₂), niobium oxide (Nb₂O₅), zirconium oxide (ZrO₂), tantalum oxide (Ta₂O₅), silicon oxide (SiO₂), or hafnium oxide (HfO₂) is used as the dielectric film. These films are composed of molecules consisting of two kinds of elements of a metal and oxygen or two kinds of elements of a metal and nitrogen, excluding amorphous silicon. The two kinds of elements are named as element A and element B, and a molecule consisting of an atom of element A and an atom of element B is defined as diatomic molecule A-B. When the dielectric film is composed of amorphous silicon, the diatomic molecule is defined as Si—Si.

When defined as described above, the diatomic molecule of the dielectric film is Al—O, Al—N, Si—Si, Ti—O, Nb—O, Zr—O, Ta—O, Si—O, and Hf—O, respectively. According to an article “David R. Lide edition in chief, Handbook of chemistry and physics, CRC Press 76th edition 1995-1996”, the energy required for isolating these diatomic molecules into atomic units is as shown in Table 1 below. In this table, the diatomic molecules are listed in the order from a smaller energy required for isolation.

TABLE 1

| | Energy required for |
|---|---|
| Diatomic molecule | isolation (kJ/mol) |
| Al—N | 297 |
| Si—Si | 327 |
| Al—O | 511 |
| Ti—O | 672 |
| Nb—O | 772 |
| Zr—O | 776 |
| Ta—O | 799 |
| Si—O | 800 |
| Hf—O | 802 |

Specifically, the diatomic molecules listed in the order from a lower light resistance of the dielectric film shown in the first embodiment are aluminum nitride (AlN), amorphous silicon, aluminum oxide (Al₂O₃), titanium oxide (TiO₂), niobium oxide (Nb₂O₅), zirconium oxide (ZrO₂), tantalum oxide (Ta₂O₅), silicon oxide (SiO₂), and hafnium oxide (HfO₂). In other words, a coating film having high reliability can be formed by using titanium oxide (TiO₂), niobium oxide (Nb₂O₅), zirconium oxide (ZrO₂), tantalum oxide (Ta₂O₅), silicon oxide (SiO₂), or hafnium oxide (HfO₂), which has higher light resistance than aluminum oxide (Al₂O₃).

In the fourth embodiment, the dielectric film is composed of 2 kinds of elements A and B, and a material wherein the energy required for isolating the diatomic molecule A-B into A and B atoms is larger than the energy required for isolating the diatomic molecule Al—O composed of aluminum (Al) and oxygen (O) into Al and O atoms was selected. Thereby, in the semiconductor laser shown in the first embodiment, the resistance of a dielectric film to laser beams can be further enlarged.

In other words, the above-described dielectric film was composed of 2 kinds of elements A and B, element A being any of titanium (Ti), niobium (Nb), zirconium (Zr), tantalum (Ta), silicon (Si), and hafnium (Hf), and element B being oxygen (O). Thereby, the reliability of the coating film can be raised compared with the case wherein aluminum oxide (Al₂O₃) is used as the dielectric film.

According to the fourth embodiment, in addition to the effects obtained by the first to third embodiments, the reliability of the coating film can be raised.

### Fifth Embodiment

A semiconductor laser according to the fifth embodiment will be described. Here, the description will be focused around difference from the first to fourth embodiments. In the first embodiment, an example of a high-output laser (output of about 50 mW or more) wherein a first coating film 8a (low reflectivity film) is formed on a first facet 8 is formed and a second coating film 9a (high reflectivity film) is formed on a second facet 9 is formed is shown. The structure wherein coating films as described above is formed can be applied not only to high-output lasers, but also to low-output lasers (output of about 10 mW) used in writing or the like.

Furthermore, a high-output laser and a low-output laser can be of a structure wherein first coating films 8a shown in the first embodiment are formed on both the first facet (front facet) and the second facet (rear facet). Alternatively, the structure wherein a first coating film 8a is formed only on the second facet (rear facet) can also be used. Specifically, the structure can also be used wherein a first coating film 8a shown in the first embodiment is formed at least one of the first facet 8 and the second facet 9 shown in FIG. 1. By forming such a structure, the reliability of the facet in the side wherein the first coating film 8a is formed can be improved, and a long-life semiconductor laser can be obtained.

In the first to fifth embodiments described above, examples applied to blue semiconductor lasers composed of a gallium nitride semiconductor were shown. However, the examples can be effectively applied to not only to the above-described blue semiconductor laser, but also other semiconductor lasers having attenuation factors larger than that of a red laser or a 780-nm laser.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2006-097786, filed on Mar. 31, 2006 including specification, claims, drawings and summary, on which the Convention priority of the present application is based, are incorporated herein by reference in its entirety.

1. A semiconductor laser comprising:
a resonator disposed along a traveling direction of a laser beam;
a first facet at a first end portion of said resonator, from which the laser beam is emitted; and
a second facet at a second end portion of said resonator, wherein
a first coating film consisting of a single layer dielectric film coats at least one of the said first facet and said second facet, and
the oscillating wavelength of the laser beam is λ and the refractive index of said dielectric film is n, and the thickness of said dielectric film is within a range between 5% and 50% of λ/4n.

2. The semiconductor laser according to claim 1, wherein
said first coating film coats said first facet, and
a second coating film having a higher reflectivity than said first coating film coats said second facet.

3. The semiconductor laser according to claim 1, wherein said semiconductor laser is a gallium nitride semiconductor laser that generates blue laser light.

4. The semiconductor laser according to claim 2, wherein said semiconductor laser is a gallium nitride semiconductor laser that generates blue laser light.

5. The semiconductor laser according to claim 1, wherein the thickness of said dielectric film is within a range between 5% and 20% of λ/4n.

6. The semiconductor laser according to claim 1, wherein said dielectric film is composed of a material selected from the group consisting of aluminum nitride, amorphous silicon, aluminum oxide, titanium oxide, niobium oxide, zirconium oxide, tantalum oxide, silicon oxide, and hafnium oxide.

7. The semiconductor laser according to claim 1, wherein said dielectric film is formed using any one of vapor deposition, sputtering and chemical vapor deposition.

8. The semiconductor laser according to claim 1, wherein
said dielectric film is composed of two elements A and B; and
the energy required to dissociate a diatomic molecule A-B composed of the elements A and B into A and B is larger than the energy required to dissociate a diatomic molecule Al—O composed of Al and O into Al and O.

9. The semiconductor laser according to claim 8, wherein
the element A is selected from the group consisting of titanium, niobium, zirconium, tantalum, silicon, and hafnium; and
the element B is oxygen.
